(19) United States
(12) Patent Application Publication
(10) Pub. No.: US 2008/0153224 A1
(43) Pub. Date: Jun. 26, 2008

(54) INTEGRATED CIRCUIT SYSTEM WITH MEMORY SYSTEM

(75) Inventors: Connie Pin Chin Wang, Mountain View, CA (US); Simon Siu-Sing Chan, Saratoga, CA (US); Angela T. Hui, Fremont, CA (US); Paul R. Besser, Sunnyvale, CA (US); Shenqing Fang, Fremont, CA (US)

Correspondence Address: FARJAMI & FARJAMI LLP, 26522 LA ALAMEDA AVENUE, SUITE 360, MISSION VIEJO, CA, 92691, US

(73) Assignees: SPANSION LLC, Sunnyvale, CA (US); ADVANCED MICRO DEVICES, INC., Sunnyvale, CA (US)

(21) Appl. No.: 11/735,229

(22) Filed: Apr. 13, 2007

Related U.S. Application Data
(60) Provisional application No. 60/871,436, filed on Dec. 21, 2006.

(51) Int. Cl. H01L 21/336

(52) U.S. Cl. 438/257; 438/649

(57) ABSTRACT

An integrated circuit system is provided including forming a memory section having a spacer with a substrate, forming an outer doped region of the memory section in the substrate, forming a contact on the outer doped region, thinning the contact for forming a thinned contact, and forming a metal plug on the thinned contact.

### TECHNICAL FIELD

The present invention relates generally to integrated circuit systems and more particularly to integrated circuit systems having a memory system.

### BACKGROUND ART

Modern electronics, such as smart phones, personal digital assistants, location based services devices, digital cameras, music players, servers, and storage arrays, are packing more integrated circuits into an ever shrinking physical space with expectations for decreasing cost. One cornerstone for electronics to continue proliferation into everyday life is the non-volatile storage of information such as cellular phone numbers, digital pictures, or music files. Numerous technologies have been developed to meet these requirements.

There are many types of non-volatile data storage, such as Hard Disk Drives, magneto-optical drives, compact disk (CD), digital versatile disk (DVD), and magnetic tape. However, semiconductor based memory technologies have advantages of very small size, mechanical robustness, and low power. These advantages have created the impetus for various types of non-volatile memories, such as electrically erasable programmable read only memory (EEPROM) and electrically programmable read only memory (EPROM). EEPROM can be easily erased without extra exterior equipment but with reduced data storage density, lower speed, and higher cost. EPROM, in contrast, is less expensive and has greater density but lacks erasability.

A newer type of memory called “Flash” EEPROM, or Flash memory, has become popular because it combines the advantages of the high density and low cost of EPROM with the electrical erasability of EEPROM. Flash memory can be rewritten and can hold its contents without power. Contemporary Flash memories are designed in a floating gate or a charge trapping architecture. Each architecture has its advantages and disadvantages.

The floating gate architecture offers implementation simplicity. This architecture embeds a gate structure, called a floating gate, inside a conventional metal oxide semiconductor (MOS) transistor gate stack. Electrons can be injected and stored in the floating gate as well as erased using an electrical field or ultraviolet light. The stored information may be interpreted as a value “0” or “1” from the threshold voltage value depending upon charge stored in the floating gate. As the demand for Flash memories increases, the Flash memories must scale with new semiconductor processes. However, new semiconductor process causes a reduction of key feature sizes in Flash memories of the floating gate architecture, which results in undesired increase in programming time, and decrease in data retention.

The charge trapping architecture offers improved scalability to new semiconductor processes compared to the floating gate architecture. One implementation of the charge trapping architecture is a silicon-oxide-nitride-oxide semiconductor (SONOS) where the charge is trapped in the nitride layer. The oxide-nitride-oxide structure has evolved to an oxide-silicon rich nitride-oxide (ORO) for charge trapping structure. Leakage and charge-trapping efficiency are two major parameters considered in device performance evaluation. Charge-trapping efficiency determines if the memory devices can keep enough charges in the storage nodes after program/erase operation and is reflected in retention characteristics. It is especially critical when the leakage behavior of storage devices is inevitable.

Memory density increase or evolution with new semiconductor technologies involves trade-offs. Some of these trade-offs include number of process steps, process technology complexities, electrical performance trade-offs, cost, and overall yield. One approach is to simplify manufacturing steps while improving electrical performance of the memory architectures.

Thus, a need still remains for an integrated circuit system with memory integration providing low cost manufacturing, improved yields, and improved electrical performance of memory in a system. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit system including forming a memory section having a spacer with a substrate, forming an outer doped region of the memory section in the substrate, forming a contact on the outer doped region, thinning the contact for forming a thinned contact, and forming a metal plug on the thinned contact.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIGS. 1A, 1B, and 1C are schematic views of examples of electronics systems in which various aspects of the present invention may be implemented;

FIG. 2 is a plan view of an integrated circuit system in an embodiment of the present invention;

FIG. 3 is a more detailed plan view of a portion of the memory systems of FIG. 2;

FIG. 4 is a cross-sectional view of the memory systems along a line segment 4-4 of FIG. 3 in an embodiment of the present invention;

FIG. 5 is a cross-sectional view of the memory systems of FIG. 4 in a source/drain forming phase;

FIG. 6 is the structure of FIG. 5 in a channel forming phase;

FIG. 7 is the structure of FIG. 6 in a plug forming phase; and

FIG. 8 is a flow chart of an integrated circuit system for manufacture of the integrated circuit system in an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the apparatus are semi-diagrammatic and not to scale and, particularly, some of the dimensions are for the clarity of presentation and are shown greatly exaggerated in the figures. In addition, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional integrated circuit surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements.

The term “processing” as used herein includes deposition of material, patterning, exposure, development, etching, cleaning, molding, and/or removal of the material or as required in forming a described structure. The term “system” as used herein means and refers to the method and to the apparatus of the present invention in accordance with the context in which the term is used.

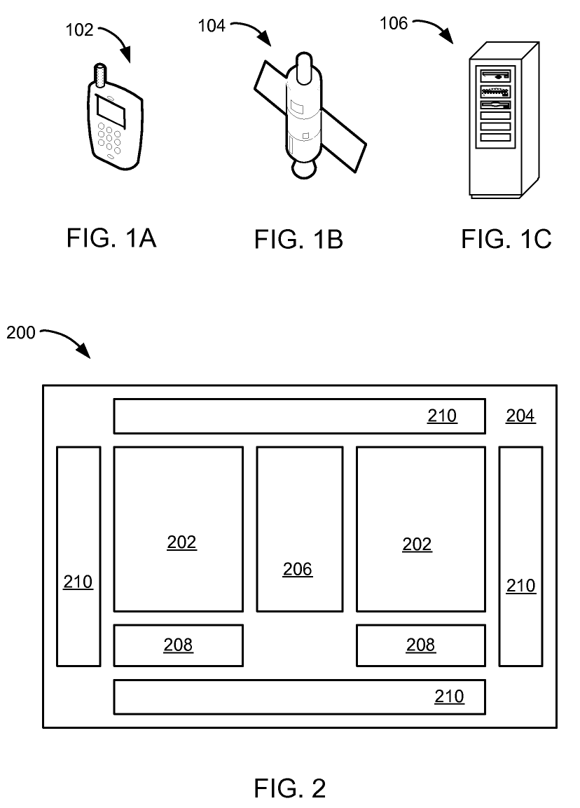

Referring now to FIGS. 1A, 1B, and 1C, therein are shown schematic views of examples of electronics systems in which various aspects of the present invention may be implemented. A smart phone 102, a satellite 104, and a compute system 106 are examples of the electronic systems using the present invention. The electronic systems may be any system that performs any function for the creation, transportation, storage, and consumption of information. For example, the smart phone 102 may create information by transmitting voice to the satellite 104. The satellite 104 is used to transport the information to the compute system 106. The compute system 106 may be used to store the information. The smart phone 102 may also consume information sent from the satellite 104.

The electronic systems, such as the smart phone 102, the satellite 104, and the compute system 106, include a one or more subsystem, such as a printed circuit board having the present invention or an electronic assembly having the present invention. The electronic system may also include a subsystem, such as an adapter card.

Referring now to FIG. 2, therein is shown a plan view of an integrated circuit system 200 in an embodiment of the present invention. The plan view depicts memory systems 202 in a substrate 204, such as a semiconductor substrate, wherein the substrate 204 has one or more high-density core regions and one or more low-density peripheral portions are formed.

High-density core regions typically include one or more of the memory systems 202. Low-density peripheral portions typically include peripheral circuitry 210, such as input/output (I/O) circuitry or transistors interfacing to the memory systems 202, and programming circuitry for individually and selectively addressing a location in each of the memory systems 202.

The programming circuitry is represented in part by and includes one or more x-decoders 206 and y-decoders 208, cooperating with the peripheral circuitry 210 for connecting the source, gate, and drain of selected addressed memory cells to predetermined voltages or impedances to effect designated operations on the memory cell, e.g. programming, reading, and erasing, and deriving necessary voltages to effect such operations. For illustrative purposes, the integrated circuit system 200 is shown as a memory device, although it is understood that the integrated circuit system 200 may other semiconductor devices having other functional blocks, such as a digital logic block, a processor, or other types of memories.

Referring now to FIG. 3, therein is shown a more detailed plan view of a portion of the memory systems 202 of FIG. 2. The plan view depicts two instances of a memory section 302, such as NAND memory series, in each column. The memory section 302 has memory cells 304 between and including a drain select line 306 and a source select line 308. The memory cells 304 have word lines 310 above bit lines 312, wherein the word lines 310 and the bit lines 312 are perpendicular to each other. The drain select line 306 and the source select line 308 are also perpendicular to the bit lines 312. A drain line 314 is perpendicular to the bit lines 312 and next to the drain select line 306. A source line 316 is perpendicular to the bit lines 312 and next to the source select line 308.

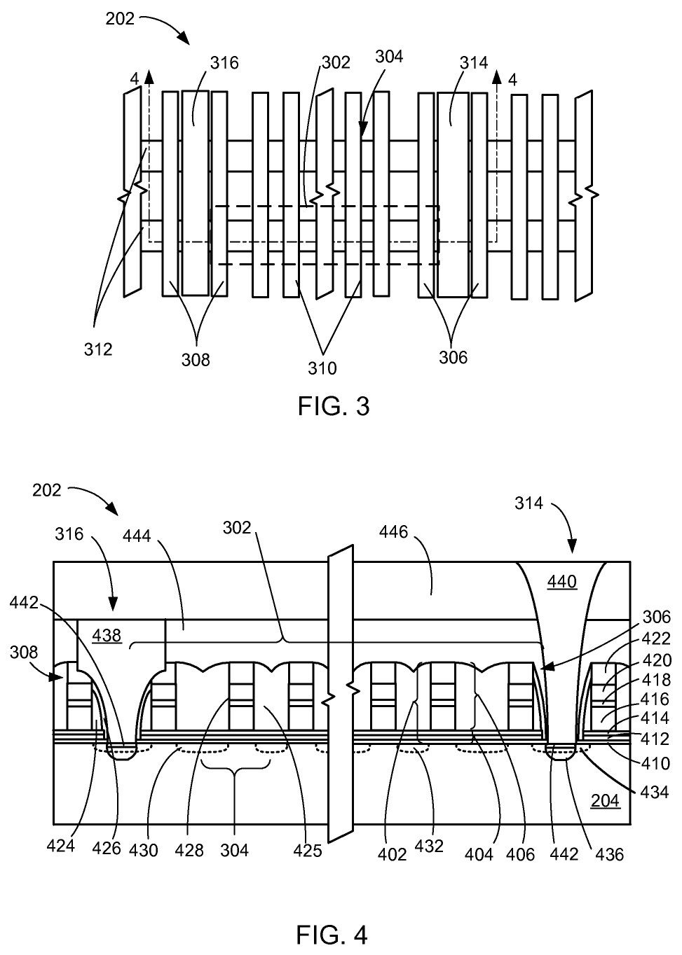

Referring now to FIG. 4, therein is a cross-sectional view of the memory systems 202 along a line segment 4-4 of FIG. 3 in an embodiment of the present invention. The cross-sectional view depicts the memory systems 202 in and over and in the substrate 204. The memory systems 202 have memory stacks 402 over the substrate 204.

Each of the memory stacks 402 includes a charge storage stack 404, such as an oxide-silicon rich nitride-oxide (ORO) stack, and stack headers 406 over the charge storage stack 404. The charge storage stack 404 is also over the substrate 204 and not under the stack headers 406. For illustrative purposes, the stack headers 406 are shown over the charge storage stack 404, although it is understood that the charge storage stack 404 may be below each of the stack headers 406 and not between adjacent instances of the stack headers 406. For example, the charge storage stack 404 may be continuous or isolate for each of the memory cells 304.

The charge storage stack 404 has a first insulator region 410, a charge trap region 412, and a second insulator region 414. The first insulator region 410, such as a bottom tunneling oxide region, is over the substrate 204. The charge trap region 412, such as a silicon rich nitride region, is over the first insulator region 410. The second insulator region 414, such as a top blocking oxide region, is over the charge trap region 412.

Each of the stack headers 406 has a semi-conducting region 416, a transition region 418, a metal region 420, and a cap region 422. The semi-conducting region 416, such as a polysilicon region, is over the substrate 204 and the charge storage stack 404. The transition region 418, such as a tungsten nitrogen (WN) region, is over the semi-conducting region 416. The metal region 420, such as a tungsten (W) region, is over the transition region 418. The transition region 418 prevents reaction between the metal region 420 and the semi-conducting region 416. The cap region 422, such as a silicon nitride (SiN) layer, is over the metal region 420.

A first spacer 424, such as an oxide spacer, is preferably along a sidewall 428 of the stack headers 406 at ends of the memory section 302 and preferably over the charge storage stack 404. A gap filler 425, such as an oxide filler, is between the stack headers 406 not at the ends of the memory section 302. A second spacer 426, such as a nitride spacer, is preferably over the first spacer 424 and the sidewall 428. The second spacer 426 is preferably over sides of the charge storage stack 404 at the ends of the memory section 302.

The cross-sectional view of the memory systems 202 depicts a first inner doped region 430, a second inner doped region 432, a first outer doped region 434, and a second outer doped region 436. The first inner doped region 430 and the second inner doped region 432 are preferably within the memory section 302. The first outer doped region 434 and the second outer doped region 436 are preferably both below a first metal plug 438, such as a tungsten (W) plug, for the source line 316 and a second metal plug 440, such as a tungsten (W) plug, for the drain line 314. The first outer doped region 434 and the second outer doped region 436 are preferably both at the ends of the memory section 302.

The first inner doped region 430, such as an n-minus doped region or a lightly doped deposition region, is preferably towards the ends of the memory section 302. The first inner doped region 430 is preferably between one of the stack headers 406 having the drain select line 306 and an adjacent instance of the stack headers 406. The first inner doped region 430 is also preferably between one of the stack headers 406 having the source select line 308 and an adjacent instance of the stack headers 406. The second inner doped region 432, such as an n-minus doped region or a lightly doped deposition region, is preferably in the substrate 204 between the stack headers 406 not at the ends of the memory section 302. A length of the first inner doped region 430 is preferably longer than a length of the second inner doped region 432.

The first outer doped region 434, such as an n-minus doped region or a lightly doped deposition region, is preferably in the substrate 204 below the first spacer 424 and the second spacer 426. The second outer doped region 436, such as an n-plus doped region, is preferably in the substrate 204. The second outer doped region 436 is not under by the second spacer 426 and the charge storage stack 404.

A thinned contact 442, such as a cobalt silicide (CoSiₓ), is preferably located at a top portion of the second outer doped region 436. A thickness of a contact (not shown) that has not undergone thinning is in the range about 300 angstroms to 1000 angstroms. A thickness of the thinned contact 442 is in a range about 100 angstroms to 150 angstroms.

A first inter-layer dielectric 444 is preferably over the gap filler 425, the memory stacks 402, and the substrate 204. The first inter-layer dielectric 444 surrounds and exposes the first metal plug 438. The first metal plug 438 connects to the thinned contact 442 and is over the second spacer 426.

A second inter-layer dielectric 446 is preferably over the first inter-layer dielectric 444 and the first metal plug 438. The second inter-layer dielectric 446 surrounds and exposes the second metal plug 440. The second metal plug 440 connects to the thinned contact 442 through the first inter-layer dielectric 444.

One of the memory cells 304 includes preferably one of the memory stacks 402 and the adjacent instances of the first inner doped region 430, the second inner doped region 432, or a combination thereof. The first inner doped region 430 and the second inner doped region 432 may function as a source or drain in the memory section 302. The first outer doped region 434 and the second outer doped region 436 may function as a source or drain of the memory section 302.

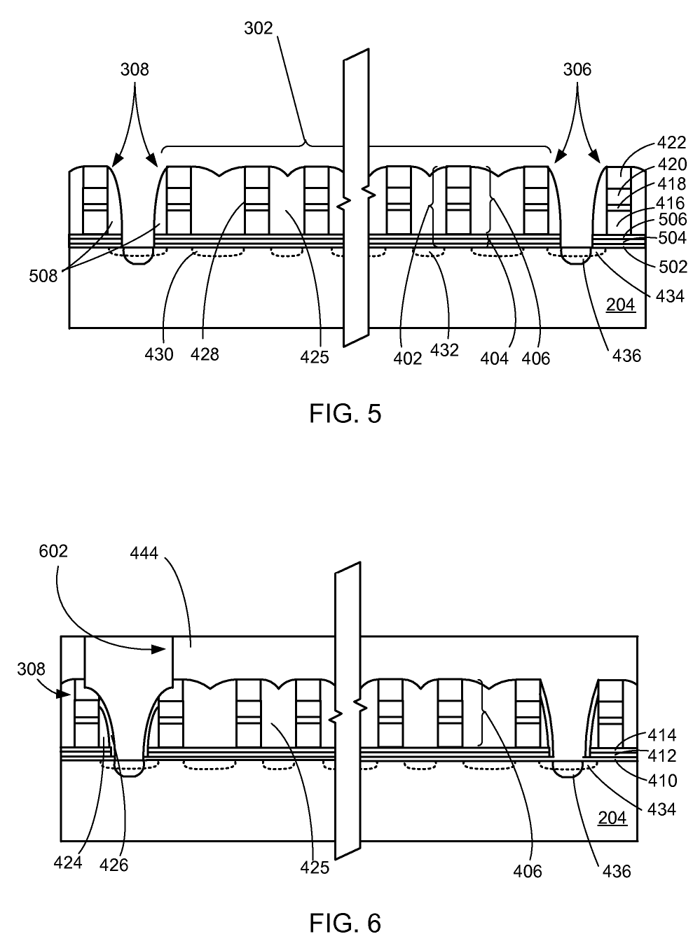

Referring now to FIG. 5, therein is shown a cross-sectional view of the memory systems of FIG. 4 in a source/drain forming phase. The cross-sectional view depicts a first insulator layer 502, such as an oxide layer, is formed over the substrate 204. A charge trap layer 504, such as a silicon-rich nitride layer (SRN or SiRN) or silicon nitride (Si_{X}N_{Y}), is formed over the first insulator layer 502. The silicon-rich nitride may be formed by a chemical vapor deposition process (CVD) using NH₃ and SiCl₂H₂ but not limited to the two chemicals. A ratio of the gases, such as NH₃:SiCl₂H₂, range from 1:40 to 1:1 can produce silicon-rich nitride with a ratio of Si to N higher than 0.75.

For illustrative purposes, the charge trap layer 504 is shown as a single layer, although it is understood that the charge trap layer 504 may have multiple layers, such as a nitride layer over a silicon rich nitride layer. Also for illustrative purposes, the charge trap layer 504 is shown as a single uniform layer, although it is understood that the charge trap layer 504 may include one or more layer having a concentration gradient, such as different gradient concentrations of silicon.

A second insulator layer 506, such as an oxide layer, is formed over the charge trap layer 504 forming the layers of the charge storage stack 404. The second insulator layer 506 may be formed over the charge trap layer 504 with a number of different processes, such as atomic layer deposition (ALD) or thermal oxidation. Alternatively, the second insulator layer 506 may be formed from a top portion of the charge trap layer 504 with slot plane antenna (SPA) oxidation.

The stack headers 406 are formed over the second insulator layer 506. The semi-conducting region 416 is formed over the second insulator layer 506. The transition region 418 is formed over the semi-conducting region 416. The metal region 420 is formed over the transition region 418. The transition region 418 prevents reaction between the metal region 420 and the semi-conducting region 416. The cap region 422 is formed over the metal region 420. The metal region 420 may be connected as the word lines 310 of FIG. 3.

The stack headers 406 may be formed in a number of ways. For example, the stack headers 406 may be formed by processing the material stack (not shown) for the semi-conducting region 416, the transition region 418, the metal region 420, and the cap region 422. Each of the stack headers 406 with the first insulator layer 502, the charge trap layer 504, and the second insulator layer 506 below form one of the memory stacks 402.

The structure having the stack headers 406 undergoes a first implantation, such as ion implantation. The first implantation preferably forms lightly doped deposition regions, such as the first inner doped region 430, the second inner doped region 432, and the first outer doped region 434, in the substrate 204 between the stack headers 406. The reference to the first implantation is not necessarily the absolute first implantation performed and is not intended to be limiting but for convenience is noted as the first.

The gap filler 425 is formed over the substrate 204 and the second insulator layer 506 surrounding the stack headers 406. The gap filler 425 and the charge storage stack 404 are processed removing the gap filler 425 and the charge storage stack 404 at the ends of the memory section 302 and between the stack headers 406 having the drain select line 306 as well as between the stack headers 406 having the source select line 308. Spacers 508 are formed along the sidewall 428 of the stack headers 406 from the removal of the gap filler 425.

A second implantation is performed to the structure having the gap filler 425 removed between the stack headers 406 having the drain select line 306 and between the stack headers 406 having the source select line 308. The second implantation preferably forms the second outer doped region 436 in the substrate 204 between the spacers 508.

The reference to the second implantation is not necessarily the absolute second implantation performed and is not intended to be limiting but for convenience is noted as the second. Also, the second designation does not necessarily refer to the next implantation following the first implantation and any number of implantation may be performed between the first implantation and the second implantation.

Referring now to FIG. 6, therein is shown the structure of FIG. 5 in a channel forming phase. An etch stop layer (not shown), such as a silicon nitride layer, is preferably formed over predetermined locations over the spacers 508. For illustrative purposes, the etch stop layer is described over the spacers 508, although it is understood that the etch stop layer may be formed in other locations. For example, the etch stop layer may be formed over the gap filler 425 and the stack headers 406.

The first inter-layer dielectric 444 is preferably formed over the gap filler 425, the spacers 508 of FIG. 5, the stack headers 406, the first outer doped region 434, the second outer doped region 436, the etch stop layer, and the substrate 204. The first inter-layer dielectric 444 preferably undergoes a planarization process, such as chemical and mechanical planarization (CMP).

A first channel 602 is preferably formed or etched in the first inter-layer dielectric 444 over and between the stack headers 406 having the source select line 308. The etching process also etches the second insulator layer 506 of FIG. 5, the charge trap layer 504 of FIG. 5, and the first insulator layer 502 of FIG. 5 forming the second insulator region 414, the charge trap region 412, and the first insulator region 410, respectively. The etching process forms the first spacer 424 and the second spacer 426 from the spacers 508 and the etch stop layer, respectively. The etching process also exposes the first outer doped region 434 and the second outer doped region 436 between the stack headers 406 having the source select line 308.

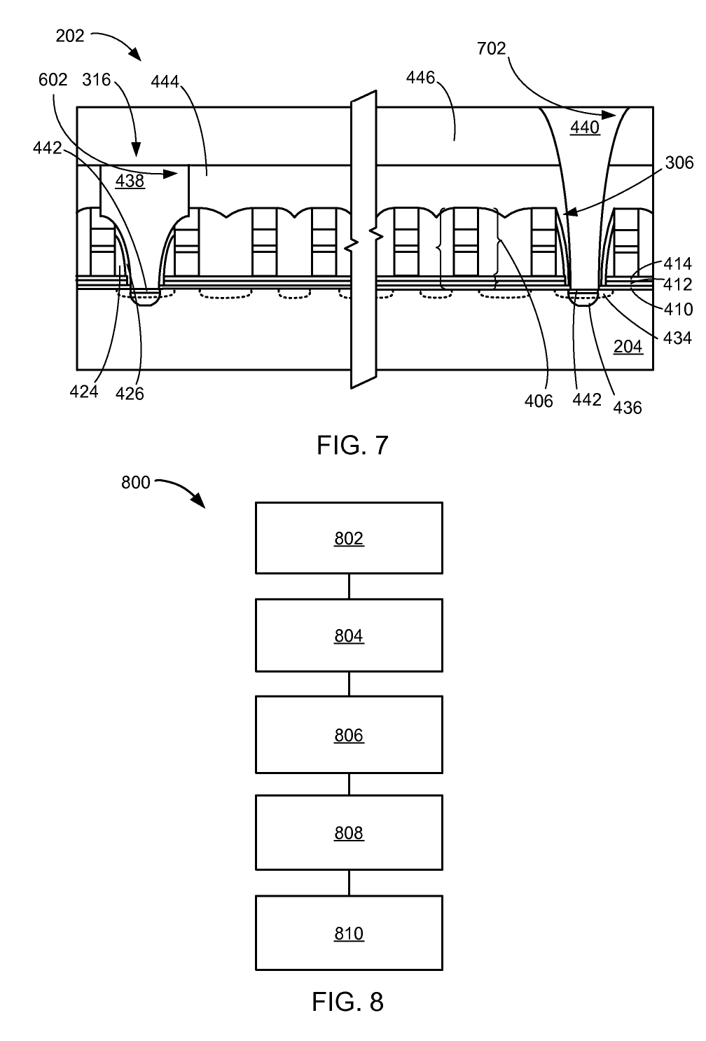

Referring now to FIG. 7, therein is shown the structure of FIG. 6 in a plug forming phase. A conductive layer, such as a cobalt salicide, (not shown), is formed over the structure of FIG. 6. The conductive layer undergoes sintering, such as rapid thermal process (RTP), diffusing the conductive layer to the surface of the second outer doped region 436. The unreacted portions of the conductive layer is removed by a number of different processes, such as etching, forming a contact (not shown), such as cobalt silicide, of the second outer doped region 436. The contact undergoes a thinning process, such as cleaning with wet clean or in-situ oxide reduction, forming the thinned contact 442, such as a thinned cobalt silicide. For example, the contact without thinning preferably has a thickness range about 300 angstroms to 1000 angstroms. The thinned contact 442 preferably has a thickness range about 100 angstroms to 150 angstroms.

A metal, such as tungsten, is deposited in the first channel 602 and over the thinned contact 442 forming the first metal plug 438. The first metal plug 438 may undergo a planarization or etch back process. The first metal plug 438 may be connected to the source line 316. For illustrative purposes, the first metal plug 438 connects to the second outer doped region 436 with the thinned contact 442, although it is understood that the first metal plug 438 may be connected to the second outer doped region 436 without the thinned contact 442.

It has been discovered that the present invention provides a connection interface with the thinned contact 442 and a doped region, such as the second outer doped region 436, in the substrate 204 reducing the resistance of the connection to the second outer doped region 436. The reduced resistance improves performance of the circuitry or the memory systems 202. Also the thinned contact 442 eliminates a need for a tungsten barrier layer (not shown) or a tungsten glue layer (not shown), such as tungsten nitride (WN) or titanium nitride (TiN), on the second outer doped region 436. Further, the thinned contact 442 or the non-thinned contact does not add manufacturing cost or steps for the integrated circuit system 200 of FIG. 2 having the peripheral circuitry 210 of FIG. 2.

The second inter-layer dielectric 446 is preferably formed over the first inter-layer dielectric 444, the first metal plug 438, and the substrate 204. The second inter-layer dielectric 446 preferably undergoes a planarization process, such as chemical and mechanical planarization (CMP).

A second channel 702 is preferably formed or etched in the first inter-layer dielectric 444 and the second inter-layer dielectric 446 over and between the stack headers 406 having the drain select line 306. The etching process also etches the second insulator layer 506 of FIG. 5, the charge trap layer 504 of FIG. 5, and the first insulator layer 502 of FIG. 5 forming the second insulator region 414, the charge trap region 412, and the first insulator region 410, respectively. The etching process forms the first spacer 424 and the second spacer 426 from the spacers 508 and the etch stop layer, respectively. The etching process also exposes the first outer doped region 434 and the second outer doped region 436 between the stack headers 406 having the drain select line 306.

The thinned contact 442 under the second channel 702 may be formed similarly as described as the thinned contact 442 under the first metal plug 438. The second metal plug 440 is formed in the second channel 702 and connects to the thinned contact 442.

For illustrative purposes, the first metal plug 438, the second metal plug 440, and the thinned contact 442 below each are described formed in separate steps and sequential levels, although it is understood that the first metal plug 438, the second metal plug 440, and the thinned contact 442 below each may be formed differently. For example, the first metal plug 438 and the second metal plug 440 may be formed concurrently as well as the thinned contact 442 below each.

Referring now to FIG. 8, therein is shown a flow chart of an integrated circuit system 800 for manufacture of the integrated circuit system 200 in an embodiment of the present invention. The system 800 includes forming a memory section having a spacer with a substrate in a block 802; forming an outer doped region of the memory section in the substrate in a block 804; forming a contact on the outer doped region in a block 806; thinning the contact for forming a thinned contact in a block 808; and forming a metal plug on the thinned contact in a block 810.

These and other valuable aspects of the embodiments consequently further the state of the technology to at least the next level.

Thus, it has been discovered that the integrated circuit system method and apparatus of the present invention furnish important and heretofore unknown and unavailable solutions, capabilities, and functional aspects for integrated systems. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. An integrated circuit system comprising:
forming a memory section having a spacer with a substrate;
forming an outer doped region of the memory section in the substrate;
forming a contact on the outer doped region;
thinning the contact for forming a thinned contact; and
forming a metal plug on the thinned contact.

2. The system as claimed in claim 1 wherein forming the contact includes forming a cobalt silicide.

3. The system as claimed in claim 1 wherein forming the metal plug includes forming a tungsten plug.

4. The system as claimed in claim 1 wherein forming the outer doped region includes forming a source region or a drain region.

5. The system as claimed in claim 1 further comprising forming an electronic system or subsystem with the integrated circuit system.

6. An integrated circuit system comprising:
forming a memory section, having a charge storage stack and a spacer, with a substrate;
forming an outer doped region of the memory section in the substrate not below the memory section;
forming a cobalt silicide on the outer doped region;
thinning the cobalt silicide for forming a thinned cobalt silicide; and
forming a tungsten plug on the thinned cobalt silicide.

7. The system as claimed in claim 6 wherein forming the memory section having the charge storage stack includes forming a silicon rich nitride portion or a nitride portion.

8. The system as claimed in claim 6 wherein forming the memory section includes forming memory cells in a series.

9. The system as claimed in claim 6 further comprising connecting a source line and the tungsten plug.

10. The system as claimed in claim 6 wherein forming the memory section includes forming an inner doped region of the memory section in the substrate.

11. An integrated circuit system comprising:
a memory section having a spacer with a substrate;
an outer doped region of the memory section in the substrate;
a thinned contact on the outer doped region; and
a metal plug on the thinned contact.

12. The system as claimed in claim 11 wherein the thinned contact includes a thinned cobalt silicide.

13. The system as claimed in claim 11 wherein the metal plug includes a tungsten plug.

14. The system as claimed in claim 11 wherein the outer doped region includes a source region or a drain region.

15. The system as claimed in claim 11 further comprising an electronic system or a subsystem with the integrated circuit system.

16. The system as claimed in claim 11 wherein:
the memory section has a charge storage stack and the spacer over the substrate;
the outer doped region of the memory section in the substrate is not below the memory section;
the thinned contact is a thinned cobalt silicide on the outer doped region; and
the metal plug is a tungsten plug on the thinned contact.

17. The system as claimed in claim 16 wherein the memory section having the charge storage stack includes a silicon rich nitride portion or a nitride portion.

18. The system as claimed in claim 16 wherein the memory section includes memory cells in a series.

19. The system as claimed in claim 16 further comprising a source line connected with the tungsten plug.

20. The system as claimed in claim 16 wherein the memory section includes an inner doped region of the memory section in the substrate.
